(19) United States
(12) Patent Application Publication
(10) Pub. No.: US 2007/0269984 A1
(43) Pub. Date: Nov. 22, 2007

(54) Method of manufacturing semiconductor device, method of manufacturing semiconductor substrate and semiconductor substrate

(75) Inventor: Nobue Araki, Shibata-shi (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 11/798,808

(22) Filed: May 17, 2007

(30) Foreign Application Priority Data
May 18, 2006 (JP) 2006-138864

(51) Int. Cl. H01L 21/302

(52) U.S. Cl. 438/689

(57) ABSTRACT

A method of manufacturing a semiconductor device and a semiconductor substrate including: a step of subjecting the semiconductor substrate to a wet process by relatively moving a process liquid and the semiconductor substrate during the wet process in an environment where there is not a static electricity removing effect with respect to the semiconductor substrate, the semiconductor substrate having a single crystal, polycrystalline, or amorphous silicon on at least a part of its surface; and a step of holding the semiconductor substrate with a jig electrified to the same extent as that of the semiconductor substrate after the wet process or a non-conductive jig. And a semiconductor substrate which is electrified to +100 V to +12 kV.

### BACKGROUND OF THE INVENTION

1. Field of the Invention

The present invention relates to a method of manufacturing a semiconductor device, a method of manufacturing a semiconductor substrate, and a semiconductor substrate.

2. Description of the Related Art

In a wet process for a silicon semiconductor substrate,

a substrate surface after hydrogen fluoride acid aqueous solution washing has a structure where a silicon atom on the outermost surface is bonded to hydrogen and the outermost surface is terminated with a hydrogen atom. It is known that this hydrogen-terminated silicon outermost surface is a chemically stable surface. However, an unbonded state is observed where all silicon atoms are not bonded to hydrogen and some silicon atoms appear in situ on the surface, and it is confirmed that there is a silicon atom with which a fluoride atom is bonded. Such a silicon atom is chemically unstable and is at a site where is easily oxidized.

For this reason, if the silicon semiconductor substrate after hydrogen fluoride acid aqueous solution washing is exposed to atmosphere at room temperature, a silicon oxide film (hereinafter referred to as natural oxide film) is formed at the silicon crystal surface due to oxygen and moisture in the air atmosphere. Further, it is known that the natural oxide film is also formed in a rinse process by pure water after hydrogen fluoride acid aqueous solution washing.

A quality of such a natural oxide film is not always good. Therefore, in the case of manufacturing the semiconductor device, when a gate insulation film etc. is formed in a situation where the silicon crystal has thereon the natural oxide film after the washing process, there is a possibility that reliability of the formed gate insulation film may deteriorate. Further, if epitaxial film formation or thin film formation is carried out in a situation where it has thereon the natural oxide film, then it may lead to poor film formation. Furthermore, when a conductive layer for contact is formed on an upper layer in the situation where it has thereon the natural oxide film, there is also a possibility that poor contact resistance may take place due to the natural oxide film which remains at an interface.

Further, when a semiconductor substrate manufacturer supplies a silicon semiconductor substrate to a device manufacturer, it is not possible to supply a silicon semiconductor substrate without natural oxide film, and it is necessary for the device manufacturer to remove the natural oxide film on the surface before manufacturing the device.

In order to avoid the above-mentioned problem with growth of the natural oxide film at room temperature in the air atmosphere etc. after the wet process (for example), it is arranged that time interval between the completion of the wet process and the next processes, such as oxidization and film formation is controlled to be within time to the extent that the growth of the natural oxide film does not cause a problem. Alternatively, there is a method of keeping it in a storage case filled up with nitrogen gas etc. before the next process after the wet process. Further, Patent Document 1 (Japanese Patent No. 3511232) discloses a technology in which a filter is provided for an apparatus of the next process so that moisture content and an amount of oxygen are controlled to keep the silicon semiconductor substrate within the apparatus of the next process after the wet process.

However, the method of controlling the time period between the completion of the wet process and the next process reduces the flexibility of the manufacturing apparatus in the case of manufacturing a semiconductor product and causes the productivity to fall, which is undesirable. Further, the method of keeping it in the storage case filled up with nitrogen gas etc., causes the handling in the keeping to be complicated, and there is a possibility of reducing the productivity, too. Furthermore, in the method of providing the filter to the apparatus of the next process as in Patent Document 1, the apparatus of the next process is occupied by the silicon semiconductor substrates after the wet process, thus there is a high possibility of reducing the flexibility of utilizing the apparatus and causing the productivity to fall.

Further, when the semiconductor substrate manufacturer supplies the silicon semiconductor substrate to the device manufacturer, using the storage case filled up with nitrogen gas etc. inevitably increases cost of manufacturing the silicon semiconductor substrate.

In view of such a situation, a technology is required which inhibits the natural oxide film from growing even when the substrate is left to stand under atmospheric environments without controlling the moisture content and the amount of oxygen.

In consideration of the above-mentioned situation, the present invention has been made and aims to provide a method of manufacturing a semiconductor device and a method of manufacturing a semiconductor substrate which inhibit a natural oxide film from growing even when being left to stand under atmospheric environments without controlling moisture content and an amount of oxygen, and a semiconductor substrate which inhibits a natural oxide film from growing even when being left to stand under atmospheric environments.

### SUMMARY OF THE INVENTION

In consideration of the above-mentioned situation, the present invention has been made and aims to provide a method of manufacturing a semiconductor device and a method of manufacturing a semiconductor substrate which inhibit a natural oxide film from growing even when being left to stand under atmospheric environments without controlling moisture content and an amount of oxygen, and a semiconductor substrate which inhibits a natural oxide film from growing even when being left to stand under atmospheric environments.

According to a preferred embodiment of the present invention, there is provided a method of manufacturing a semiconductor device including a step of subjecting a semiconductor substrate to a wet process by relatively moving a process liquid and the above-mentioned semiconductor substrate when subjecting the semiconductor substrate to the wet process in an environment where there is not a static electricity removing effect with respect to the above-mentioned semiconductor substrate, the semiconductor substrate having a single crystal, polycrystalline, or amorphous silicon on at least a part of its surface, and a step of holding the above-mentioned semiconductor substrate with a jig electrified to the same extent as that of the above-mentioned semiconductor substrate after the above-mentioned wet process or a non-conductive jig.

At this time, it is desirable that the above-mentioned process liquid is a hydrogen fluoride acid aqueous solution.

Further, it is desirable that the above-mentioned non-conductive jig is made of polypropylene (PP).

Furthermore, in the step of holding the above-mentioned semiconductor substrate with the non-conductive jig, it is desirable that a dummy substrate with the same potential as that of the above-mentioned semiconductor substrate is held to be adjacent to the above-mentioned semiconductor substrate.

According to another preferred embodiment of the present invention, there is provided a method of manufacturing a semiconductor substrate including a step of subjecting the semiconductor substrate to a wet process by relatively moving a process liquid and the above-mentioned semiconductor substrate when subjecting the semiconductor substrate to the wet process in an environment where there is not a static electricity removing effect with respect to the above-mentioned semiconductor substrate, the semiconductor substrate having a single crystal, polycrystalline, or amorphous silicon layer on at least its surface, and a step of holding the above-mentioned semiconductor substrate with a jig electrified to the same extent as that of the above-mentioned semiconductor substrate after the above-mentioned wet process or a non-conductive jig.

The semiconductor substrate according to the preferred embodiment of the present invention is a semiconductor substrate which has a single crystal, polycrystalline, or an amorphous silicon layer at least on its surface and is electrified to +100 V to +12 kV.

In addition, in the present invention, by “wet process” is meant a process using water or an aqueous solution, such as a wet etching process, a washing process, etc. to be performed for a semiconductor substrate.

According to the present invention, it is possible to provide the manufacture method of the semiconductor device and the manufacture method of the semiconductor substrate for inhibiting the growth of the natural oxide film, without controlling the moisture content and the amount of oxygen, even when it is left to stand under atmospheric environments, and provide the semiconductor substrate in which the growth of the natural oxide film is inhibited even when it is left to stand under atmospheric environments.

### BRIEF DESCRIPTION OF THE DRAWINGS

FIGS. 1A to 1G are diagrams for explaining a process flow for manufacturing a transistor with respect to a first preferred embodiment.

FIG. 2 is a diagram for explaining a situation where a silicon wafer is held with respect to the first preferred embodiment.

FIG. 3 is a graph showing results of measuring lifetime with respect to Example.

FIG. 4 is a graph showing results of measuring absorption peaks by way of ATR (attenuated total reflection) method with respect to Example.

FIG. 5 is a graph showing results of measuring thicknesses of an oxide film with respect to Example.

FIG. 6 is a graph showing results of measuring lifetime with respect to Comparative Example.

### DESCRIPTION OF THE PREFERRED EMBODIMENTS

Hereafter, the preferred embodiments of a method of manufacturing a semiconductor device, a method of manufacturing a semiconductor substrate, and a semiconductor substrate in accordance with the present invention will be described with reference to the accompanying drawings. Here, a silicon wafer of a single crystal will be described as an example of the semiconductor substrate.

### First Preferred Embodiment

Firstly, a preferred embodiment of the method of manufacturing the semiconductor device in accordance with the present invention will be described with reference to an n-type field effect transistor.

### Manufacture Method

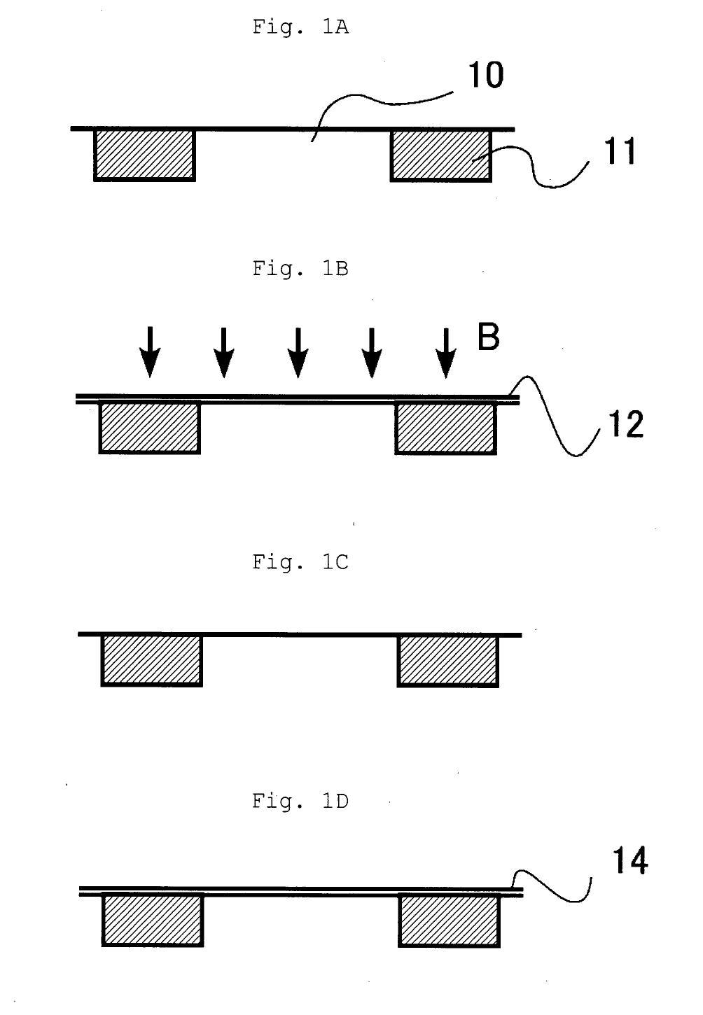

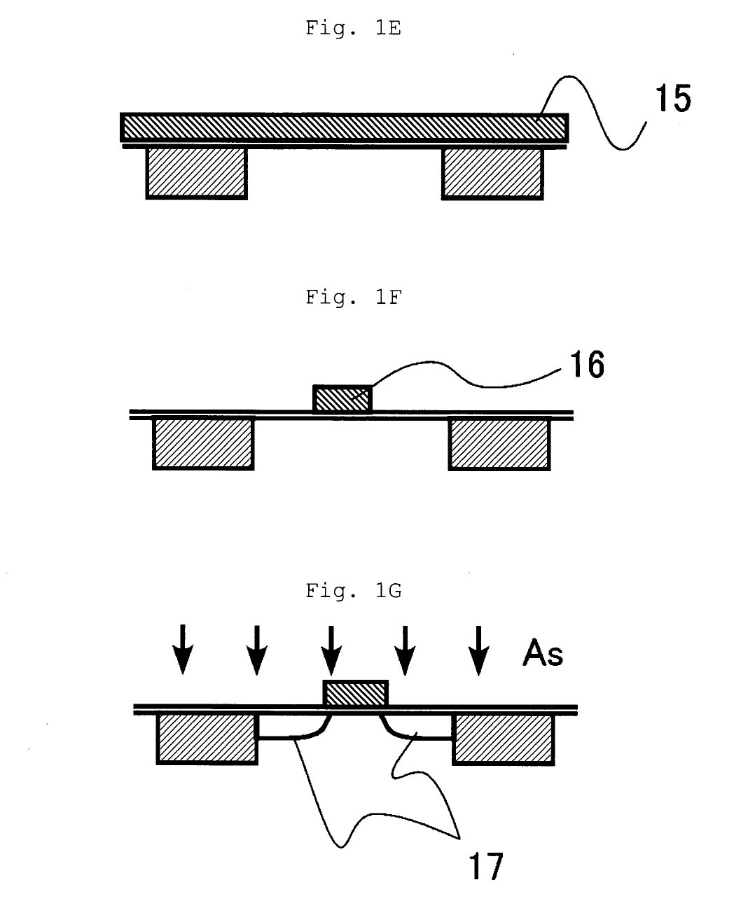

FIGS. 1A to 1G are diagrams for explaining a process flow for manufacturing a transistor with respect to the first preferred embodiment.

As shown in FIG. 1A, an element isolation area 11 is formed at a surface of a p-type (100) silicon wafer 10 by way of, for example, the STI (Shallow Trench Isolation) method, and an element area including a source, a drain, and a channel area is formed.

Next, as shown in FIG. 1B, in order to adjust a threshold value of the transistor, B (boron) is introduced by way of ion implantation on the element area through a thermal oxidation film 12 which is on the element area.

Then, as shown in FIG. 1C, the thermal oxidation film 12 on the element area is removed by means of a wet process unit. This removal is performed by means of an etching solution, such as ammonium fluoride (NH₄F) etc.

Then, pre-treatment before forming a gate oxide film 14 is carried out.

Firstly, within a batch-type wet process unit, the silicon wafer (silicon semiconductor substrate) held at a carrier made from Teflon (registered trademark) is processed, and the natural oxide film on the silicon wafer is removed with a hydrogen fluoride acid aqueous solution. At this time, the hydrogen fluoride acid aqueous solution which is a process liquid is circulated with a circulation system during the wet process to relatively move the process liquid and the silicon wafer. A circulation flow rate of the hydrogen fluoride acid aqueous solution at this time is for example, 5 L/min to 20 L/min.

Next, pure water is used as the process liquid, and the silicon wafer (silicon semiconductor substrate) held at the carrier made from, for example, Teflon (registered trademark) is also subjected to a rinse process within the batch-type wet process unit. Also at this time, the pure water which is the process liquid is supplied (overflow) and circulated during the wet process to relatively move the process liquid and the silicon wafer. A water supply flow rate of the pure water at this time is 5 L/min to 20 L/min, for example.

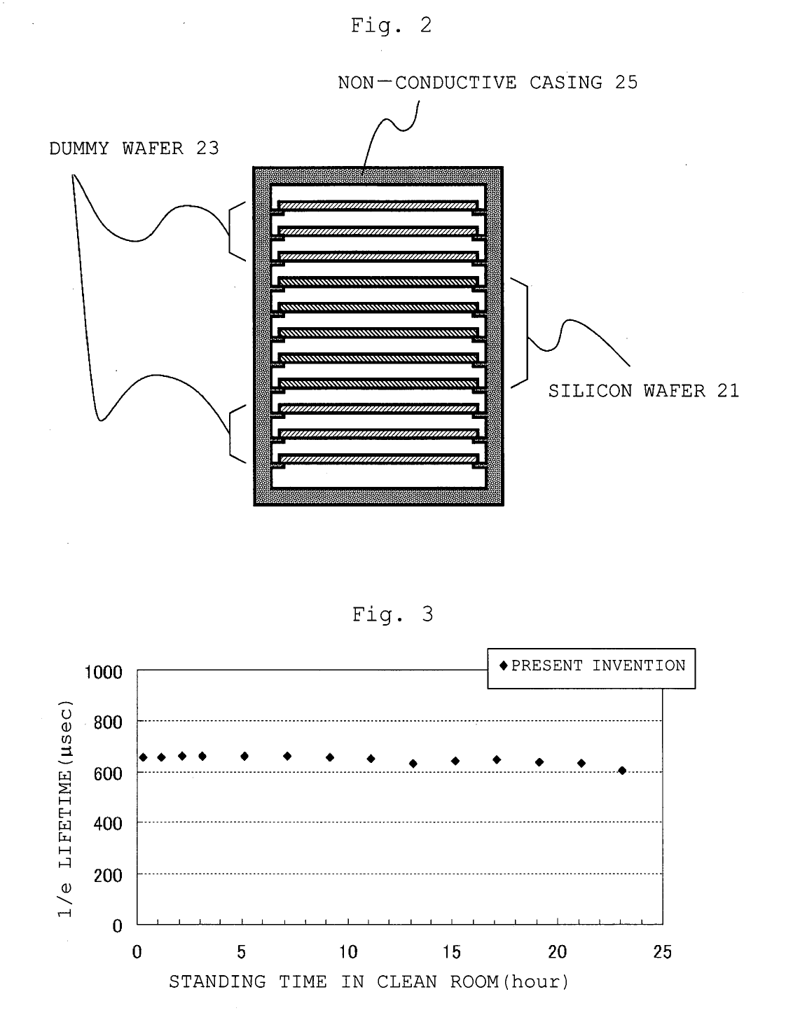

Then, being dried by way of spin drying, the silicon wafer is kept in the air atmosphere after drying. As a jig (carrier, casing, etc.) which holds the silicon wafer when it is dried and kept, a non-conductive material is used which does not remove static electricity of the silicon wafer electrified during a washing process, such as that formed of polypropylene (PP), for example. Further, in this case, as shown in FIG. 2, the dummy wafer 23 which is subjected to the similar washing process to that for the above-mentioned silicon wafer 21 is held at a non-conductive carrier 25 so as to be adjacent to the silicon wafer 21.

According to the wet process as described above, during the time interval between end of drying and the keeping, it is processed in an environment where there is not an effect of removing the static electricity occurred in the silicon wafer. In other words, inside the unit by which the silicon wafer is processed or inside a room, the removal of the static electricity from the silicon wafer is not carried out by way of UV light irradiation, operation of ionizer, grounding, etc., for example.

In addition, if it is not necessary for the above-mentioned wet process to be performed within the batch-type unit and the process liquid and the silicon wafer move relatively during the process, then a sheet-fed type wet process unit may be used.

Further, in the wet process unit, a method of relatively moving the process liquid and the silicon wafer may be not only one that circulates the process liquid but also one that vibrates the process liquid by an ultrasonic wave and one that swings and rotates the silicon wafer mechanically, for example. Alternatively, it may be a method of manually moving up and down the carrier with which the silicon wafer is held. Furthermore, it is also possible to combine them.

Further, although it is desirable that the process liquid for removing the natural oxide film is the hydrogen fluoride acid aqueous solution in view of the ease of availability, high purity, etc., it may be an ammonium fluoride solution etc., for example, as long as it is a process liquid with which the outermost surface of the silicon wafer is terminated with a hydrogen atom after removing the oxide film. Although, in the above-described flow, the removal of the thermal oxidation film and the pre-treatment of the gate insulation film are separately carried out, a flow may be employed in which the removal of the thermal oxidation film and the pre-treatment of the gate insulation film are carried out at the same time.

Further, when drying and keeping the silicon wafer, the jig which holds the silicon wafer and is made of the non-conductive material (non-conductive jig) is desirably made of polypropylene (PP), considering that the static electricity is not discharged and that a keeping system has plus (positive) electrification even if the static electricity in the silicon wafer and the static electricity in the jig are cancelled. However, it is possible to use an ABS resin, polyether ether ketone (PEEK), etc., for example. Furthermore, the jig for holding the silicon wafer is not limited to one that is made of the non-conductive material, but it is also possible to use, for example, a jig electrified to the same extent as that of the silicon wafer, a jig formed of an electret in which electric charge is stored, for example, in a polymer material, etc.

Further, drying the above-mentioned silicon wafer may be not only the spin drying but also air drying by using hydrophobicity of the silicon wafer surface for example, after the hydrogen fluoride acid aqueous solution process.

Next, as shown in FIG. 1D, after pre-treating the gate oxide film, the silicon wafer kept for arbitrary time period in the air atmosphere is processed in an oxidization furnace to form the gate oxide film 14.

Then, as shown in FIG. 1E, a polycrystalline silicon layer 15 is deposited on the gate oxide film by way of an LPCVD (Low Pressure Chemical Vapor Deposition) method.

As shown in FIG. 1F, by way of lithography and reactive ion etching, this polycrystalline silicon layer 15 is patterned to form a gate electrode 16 of the transistor.

Then, as shown in FIG. 1G, source and drain areas 17 are formed by way of As (arsenic) ion implantation and activation of the ion by heat treatment. Thus, an n-type field effect transistor is formed on the silicon wafer 10. Formation of an interlayer film, a contact hole, and a wiring layer after forming the transistor will not be described in the present specification.

Although the preferred embodiment which applies the present invention to the pre-treatment of the gate insulation film is described above, the present invention can be applied not only to the pre-treatment of the gate insulation film but also to a pre-treatment of a capacitor insulation film, a pre-treatment of epitaxial film formation or thin film formation, or a pre-treatment at the time of forming a conductive layer (polycrystalline silicon, metal, etc.) after forming the contact hole in manufacture of the semiconductor device, for example.

Further, the gate insulation film is not necessarily limited to the thermal oxidation film of a single layer; it may be, for example, an oxide film by way of vapor deposition, a high dielectric constant film, or a composite film of a thermal oxidation film and a high dielectric constant film etc.

### Operation and Effect

According to the present preferred embodiment, in the case where the oxide film formed on the silicon wafer is removed by the wet process, the silicon surface is terminated with hydrogen. In addition to this, as the process liquid and the silicon wafer move relatively, static electricity takes place in the silicon wafer so that the silicon wafer is positively electrified. It is thought that generation of this static electricity is based on friction electrification or flow electrification in the process liquid.

Then, during a subsequent wet process which is the rinse process by pure water, the electrification state of the silicon wafer is also maintained due to the relative movement of the process liquid and the silicon wafer.

In addition, although the pure water rinse is performed after the hydrogen fluoride acid aqueous solution process of removing the natural oxide film in the present preferred embodiment, it has been found in experiments by the present inventor that the silicon wafer is already electrified positively with the static electricity after the hydrogen fluoride acid aqueous solution process and before the pure water rinse process.

While being dried and kept, the silicon wafer is held by the jig which is arranged to be able to maintain the static electricity, whereby the positive electrification state of the silicon wafer is maintained. In other words, when the silicon wafer is accommodated in the jig made of a non-conductive material, such as the carrier and the case, the static electricity of the silicon wafer is not removed through the carrier or the case. But, since an atmosphere electric charge is 0 V, the electric charge is neutralized when the positively electrified silicon wafer is left to stand in the atmosphere. Thus, there is a possibility that the positive electric charge in the silicon wafer may be removed. Then, in the present preferred embodiment, as shown in FIG. 2, the dummy wafer which is subjected to the washing process similar to that for the silicon wafer is held at the carrier so as to be adjacent to the silicon wafer. Thus, the silicon wafer is surrounded by the dummy wafer and another silicon wafer which have an equivalent positive electric charge. Therefore, a potential of an environment in which the silicon wafer is placed is equivalent to a potential of the silicon wafer, and the positive electric charge is prevented from being removed from the silicon wafer. In addition, at this time, as long as the dummy wafer holds the equivalent positive electric charge, it may not necessarily be a wafer which is subjected to the washing process similar to that for the silicon wafer, but it may be a wafer electrified by way of another method. Further, the dummy wafer is not necessarily a wafer made of a silicon material.

On the other hand, when using the jig which is made of, for example, an electret and electrified to the same extent as that of the silicon wafer, such as the carrier and the case, the potential of the environment is equivalent to that of the silicon wafer, so that there is no need to cope with the environmental potential.

During the time period between the wet process and the keeping after the drying, the process is carried out under the environment where the static electricity occurred in the silicon wafer is not removed, whereby the positive electrification of the silicon wafer which is terminated with hydrogen is maintained. For this reason, even if oxidation reaction between an oxidization seed and a silicon atom does not progress and the silicon wafer is left to stand in the atmosphere, it is possible to inhibit the natural oxide film from growing.

Thus, even if it is left to stand in the air atmosphere after the pre-treatment of the gate insulation film, the natural oxide film hardly grows on the wafer. Therefore it is possible to maintain high reliability of the gate insulation film formed thereafter. Further, since a deviation in natural oxide film thickness does not arise due to a variation in standing time of gate insulation film formation after the pre-treatment, it is possible to form the gate insulation film whose film thickness and quality are stable. Furthermore, when the silicon wafer is left to stand, it is not necessary to manage time until the next step, and it is necessary to control neither the moisture content nor the amount of oxygen, whereby productivity is not remarkably reduced for natural oxide film control.

Further, also when the present invention is applied to the pre-treatment of the capacitor insulation film as described above, it is possible to obtain the effects similar to those in the case where it is applied to the gate insulation film. Furthermore, if it is carried out as the pre-treatment of the epitaxial film formation or the thin film formation, it becomes possible to avoid poor film formation caused by existence of the natural oxide film. Still further, since there is no association with the natural oxide film and there is not a problem of the film thickness variation, it becomes possible to realize stable and low contact resistance when it is applied to the pre-treatment in the case of forming the contact hole.

### Second Preferred Embodiment

Next, a second preferred embodiment of the method of manufacturing the semiconductor substrate in accordance with the present invention will be described with reference to the silicon wafer.

Firstly, a silicon single crystal ingot is pulled up by the Czochralski method (the CZ method). Then, outer diameter grinding is carried out by a three dimension grinding machine so that the silicon ingot may have a desired diameter.

Next, a wafer is cut off by slicing. Each of the cut-off wafers is lapped to correct a wafer shape, a variation in a surface distorted layer occurred by slicing.

Next, the silicon wafer is chamfered in order to prevent the wafer from being chipped by the device process. Then, chemical etching is performed in order to remove the surface distorted layer which remains in a crystal due to the lapping or chamfering. Then, the wafer surface is subjected to ML (mirror like) polish to be a mirror surface.

Then, in order to remove particulates, organic chemicals, and metal impurities on the wafer, the RCA cleaning process is performed, to form a chemical oxide film on the wafer surface.

Subsequently, a process is performed which is similar to the pre-treatment of the gate oxidization as described in the first preferred embodiment. According to such processes, the chemical oxide on the silicon wafer is removed, and the silicon surface is terminated with hydrogen to be a chemically stable surface. Further, since the silicon wafer is kept positively electrified, even if it is left to stand in the air atmosphere thereafter, the growth of the natural oxide film is inhibited.

Thus, the silicon wafer manufactured according to the present preferred embodiment does not require special atmosphere management except for electrification maintenance of the silicon wafer for inhibiting the growth of the natural oxide film. Therefore, it becomes easy to supply the silicon semiconductor substrate which permits omission of the oxide film removal process before manufacturing devices.

### Third Preferred Embodiment

Next, the semiconductor substrate and a third preferred embodiment in accordance with the present invention will be described with reference to the silicon wafer.

In the silicon wafer of the present preferred embodiment, silicon is exposed to the entire surface or a part of it, and the silicon surface is terminated with hydrogen. It is positively electrified with the static electricity.

The silicon surface is thus terminated with hydrogen and positively electrified, whereby the oxidation reaction between the oxidization seed and silicon atom does not progress and it is possible to inhibit the natural oxide film from growing even if it is in an oxidizing atmosphere, such as the air atmosphere.

Here, it is desirable that the potential of the silicon wafer is within a range of +100 V to +12 kV. This is because the natural oxide film growth inhibition effect in the air atmosphere is not sufficient if the potential is lower than 100 V. Further, if it is higher than +12 kV, the element on the silicon wafer may break down due to static discharge damage or the silicon wafer surface may be damaged as the electric charge moves from the silicon wafer.

In order to obtain the still more reliable effects of inhibiting the growth of the natural film and to secure sufficient room for the static damage, it is more desirable for the potential of the silicon wafer to be within the range of +1 kV to +10 kV.

In addition, in the preferred embodiments 1, 2, and 3 as described above, although the description is carried out with reference to the single crystal silicon wafer as an example of the semiconductor substrate, the present invention is not necessarily applied to the single crystal silicon wafer, but may be applied to a wafer in which silicon is epitaxially grown at a part of or the whole surface of the substrate, as long as it is a semiconductor substrate which has a single crystal, polycrystalline, or amorphous silicon at least at a part of its surface, for example, an SOI (Silicon On Insulator).

Further, in the above-mentioned preferred embodiments 1 and 2, although the present invention is applied to the wet etching process of removing the silicon oxide film as the desirable embodiments of the present invention, a mechanism with which the natural oxide film of the positively electrified silicon wafer is inhibited from growing works also in the semiconductor substrate in which a thin silicon oxide film, such as chemical oxide, is formed. Therefore, the present invention provides an effect in the wet etching process for forming a thin silicon oxide film with a thickness of 10 Å or less, the washing process after forming a thin oxide film, etc. In the third preferred embodiment, the semiconductor substrate in which the silicon surface is terminated with hydrogen is described as the desirable embodiment of the present invention. However, even if the silicon surface is not terminated with hydrogen, the mechanism of inhibiting the growth of the natural oxide film works, so that an effect can be demonstrated when the oxide film on silicon has a thickness of 10 Å or less also in the semiconductor substrate in which the silicon surface is not terminated with hydrogen.

In the above, the preferred embodiments of the present invention are described, referring to particular examples. In the description of the preferred embodiments, with respect to semiconductor fabrication machines, semiconductor device manufacture methods, semiconductor substrate keeping method, etc., some parts are not described which are not directly necessary to describe the present invention. However, it is possible to suitably choose and use an element in connection with the semiconductor fabrication machines, the semiconductor device manufacture method, the semiconductor substrate keeping method, etc. as needed.

In addition, any method for manufacturing a semiconductor device, any method for manufacturing a semiconductor substrate, and any semiconductor substrate which include the elements of the present invention and can be suitably modified by persons skilled in the art are included in the scope of the present invention.

Although example and comparative example of the present invention will be described hereafter, referring to the drawings, the present invention is not limited thereto.

### EXAMPLE

First, a P-type (100) silicon wafer having a diameter of 8 inches was prepared which had been pulled up by the Czochralski method (the CZ method), and set off by 0.5° in the <0-11> direction. After a surface was subjected to a mirror like (ML) polish process, the RCA cleaning process was performed for this silicon wafer to form thereon a chemical oxide film with a thickness of approximately 6 to 10 Å.

Then, this wafer was immersed in a hydrogen fluoride acid aqueous solution at a concentration 5% for 10 minutes. During the immersion, the hydrogen fluoride acid aqueous solution was circulated within a wet process unit tank, and the silicon wafer was loaded at a carrier made of a Teflon (registered trademark) material, and manually moved up and down to swing. Subsequently, the silicon wafer was immersed in pure water for 10 minutes, and subjected to a rinse process, during which time the pure water was circulated within the tank to overflow and swing. Both in the hydrogen fluoride acid process and the rinse process, the swing was manually carried out for 1 min by a distance of 50 mm for up and down motion and at a relative velocity of approximately 2 sec for one round trip, i.e., about 50 mm/sec. Since the silicon wafer in which a chemical oxide on its surface was removed by hydrogen fluoride acid aqueous solution after the rinse was a hydrophobic surface, a particular drying process was not performed.

When the potential due to the surface static electricity of this silicon wafer was measured by an electrostatic electrometer (SK-030/200, manufactured by KEYENCE Corporation, Osaka, Japan), it was +1 kV to +10 kV.

Then, the silicon wafer was kept in the carrier and case made of non-conductive polypropylene (PP) in the air atmosphere and upper and lower slots of the carrier were filled with the dummy wafers whose surrounding environmental potential was the same as that of the silicon wafer. In addition, the dummy wafer was made of a silicon material and subjected to the process similar to that for the silicon wafer to provide the same potential. Furthermore, the place where the silicon wafer was processed and kept was a place where there was no effect to remove the static electricity, such as an ionizer, a UV light, grounding, etc.

In order to investigate a change in a surface recombination center of the silicon wafer having been subjected to the above-mentioned process, a time change in a lifetime value was measured by using LTA-1200EP (manufactured by Kobelco Research Institute, Inc., Kobe, Japan) by way of the Microwave Photo Conductive Decay (μ-PCD) method. At this time, electric resistivity of the silicon wafer was 17 Ωcm, and the storage case made of the non-conductive polypropylene (PP) was used. The storage case containing the silicon wafer was left to stand inside a clean room to monitor the lifetime for 24 hours.

The measuring results are shown in FIG. 3. As is clear from FIG. 3, there is no change in the lifetime value for 24 hours. Therefore, it was found that there was no change in the surface recombination center for 24 hours. In other words, a change to be observed electrically (for example, removal of terminating hydrogen etc.) did not occur in a surface state.

Next, the silicon wafer having been subjected to the above-mentioned process was sealed in the storage case made of the non-conductive polypropylene (PP) and kept in the general air atmosphere outside the clean room. Then, by means of an infrared spectrum apparatus (IFS-120HR, available from Bruker Optics Inc, Billerica, Mass., U.S.A.) using a multiple reflection attenuated total reflection (ATR) method, absorption peaks (Si—H2;2100 cm-1, Si—H3;2140 cm-1) of the hydrogen terminal and absorption peaks (O2Si—H2;2200 cm-1, O3 Si—H;2250 cm-1) of silicon back bond oxidization were measured at 28 hours after and 172 hour after the wet process.

The measuring results are shown in FIG. 4. As is clear from FIG. 4, it can be seen that even if 172 hours elapse after the wet process, the absorption peaks of the hydrogen terminal and the absorption peaks of the silicon back bond oxidization do not change, and that the back bond oxidization which is a preceding step of the growth of the natural oxide film is inhibited.

The silicon wafer having been subjected to the above-mentioned process was kept in the storage case made of the non-conductive polypropylene (PP), and it was left to stand in the clean room. Then, changes over time in the oxide film thickness of the silicon wafer surface were monitored. The measurement of the oxide film thickness was carried out by means of an ellipsometer (AUTO-ELIII available from RUDOLPH Technologies Inc., Flanders, N.J., U.S.A.), where a refractive index of the film was set as 1.46. In addition, a lower limit of the measurement of the ellipsometer used for the measurement was 0.6 nm (6 Å).

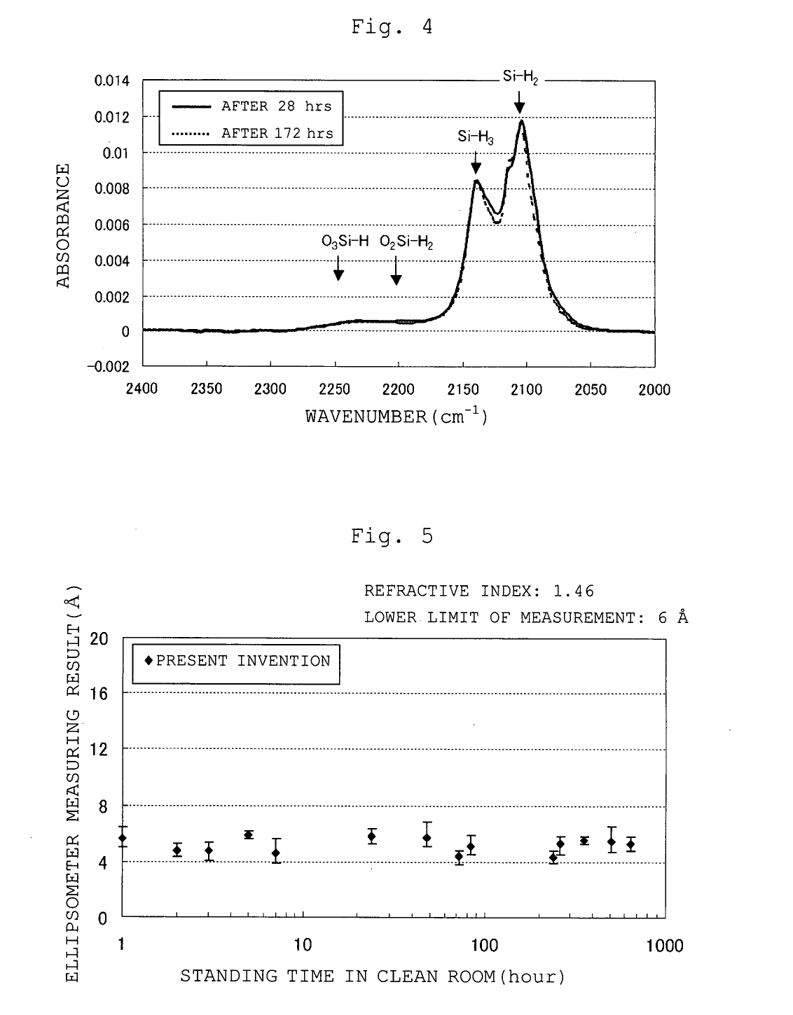

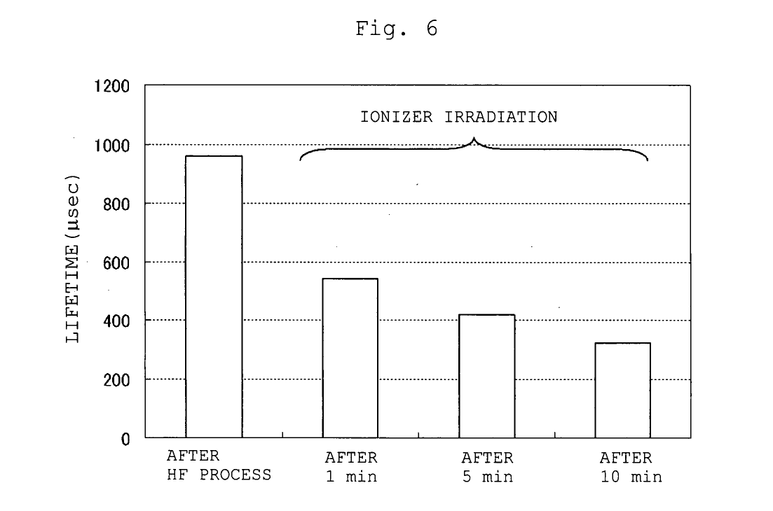

The measuring results are shown in FIG. 5. As is clear from FIG. 5, the oxide film thickness is equal to or less than a lower limit value of the measurement even approximately 600 hours after.

### COMPARATIVE EXAMPLE

With respect to the wafer having been subjected to the process similar to that for the above-mentioned Example, by means of a blow-type ionizer (SFJ-F010, manufactured by KEYENCE Corporation, Osaka, Japan) changes of the surface recombination center were measured by way of the μ-PCD method in the case of removing electric charges for 10 minutes. The results are shown in FIG. 6. The lifetime value decreases as time passes after removing the static electricity. Therefore, it can be seen that unlike Example the recombination center increases and the wafer surface is electrically unstable.

The results of this Example and Comparative Example show that, according to the present invention, the growth of the natural oxide film can be inhibited and the electrically stable surface which does not have the natural oxide film can be maintained in the oxidizing atmosphere, such as air environment, by providing the positive electric charge to the silicon surface terminated with hydrogen.

1. A method of manufacturing a semiconductor device comprising:
a step of subjecting a semiconductor substrate to a wet process by relatively moving a process liquid and said semiconductor substrate during the wet process in an environment where there is not a static electricity removing effect with respect to said semiconductor substrate, said semiconductor substrate having a single crystal, polycrystalline, or amorphous silicon on at least a part of its surface; and
a step of holding said semiconductor substrate with a jig electrified to the same extent as that of said semiconductor substrate after said wet process or a non-conductive jig.

2. The method of manufacturing the semiconductor device according to claim 1, wherein said process liquid is a hydrogen fluoride acid aqueous solution.

3. The method of manufacturing the semiconductor device according to claim 1, wherein said non-conductive jig is made of polypropylene (PP).

4. The method of manufacturing the semiconductor device according to claim 1, wherein a dummy substrate with the same potential as that of said semiconductor substrate is held to be adjacent to said semiconductor substrate in the step of holding said semiconductor substrate with the non-conductive jig.

5. The method of manufacturing the semiconductor device according to claim 3, wherein a dummy substrate with the same potential as that of said semiconductor substrate is held to be adjacent to said semiconductor substrate in the step of holding said semiconductor substrate with the non-conductive jig.

6. A method of manufacturing a semiconductor substrate comprising:
a step of subjecting said semiconductor substrate to a wet process by relatively moving a process liquid and said semiconductor substrate during the wet process in an environment where there is not a static electricity removing effect with respect to said semiconductor substrate, said semiconductor substrate having a single crystal, polycrystalline, or amorphous silicon layer on at least its surface; and
a step of holding said semiconductor substrate with a jig electrified to the same extent as that of said semiconductor substrate after said wet process or a non-conductive jig.

7. A semiconductor substrate having a single crystal, polycrystalline, or amorphous silicon layer on at least its surface, and being electrified to +100 V to +12 kV.

8. The method of manufacturing the semiconductor device according to claim 2, wherein said non-conductive jig is made of polypropylene (PP).

9. The method of manufacturing the semiconductor device according to claim 2, wherein a dummy substrate with the same potential as that of said semiconductor substrate is held to be adjacent to said semiconductor substrate in the step of holding said semiconductor substrate with the non-conductive jig.
